(19) United States
(12) Patent Application Publication
(10) Pub. No.: US 2026/0113928 A1
(43) Pub. Date: Apr. 23, 2026

(54) SEMICONDUCTOR STRUCTURE AND METHOD OF MANUFACTURING THE SAME

(71) Applicant: NANYA TECHNOLOGY CORPORATION, New Taipei City (TW)

(72) Inventor: Szu-Yao CHANG, New Taipei City (TW)

(21) Appl. No.: 18/918,107

(22) Filed: Oct. 17, 2024

(51) Int. Cl. H10B 12/00

(52) U.S. Cl. CPC H10B 12/395; H10B 12/0383; H10B 12/482; H10B 12/485

(57) ABSTRACT

A method of fabricating a semiconductor structure includes depositing a first dielectric layer on a substrate; depositing a second dielectric layer on the first dielectric layer; forming a capacitor in the first dielectric layer and the second dielectric layer; depositing a first insulating layer on the second dielectric layer and the capacitor; forming a word line structure on the first insulating layer; depositing a second insulating layer on the word line structure; forming a channel hole in the second insulating layer, the word line structure, and the first insulating layer, wherein the channel hole includes a first section with a trumpet shape opening and a second section below the first section; forming a vertical channel in the second section of the channel hole; and forming a landing pad in the first section of the channel hole. A semiconductor structure is also disclosed.

### BACKGROUND

### Field of Invention

The present disclosure relates to a semiconductor structure and a method of manufacturing the same.

### Description of Related Art

As electronic devices become lighter and thinner, semiconductor devices, such as dynamic random access memory (DRAM) become more highly integrated. Further, the performance of the DRAM is improved via shortening the pitch between the semiconductor structures in the DRAM. In addition to increasing the difficulty of the manufacturing process, the components in the semiconductor structures are also prone to leakage resulting from too close distances because of shrinking the size of the semiconductor structure.

### SUMMARY

An aspect of the disclosure provides a method of fabricating semiconductor structure. The method includes depositing a first dielectric layer on a substrate; depositing a second dielectric layer on the first dielectric layer; forming a capacitor in the first dielectric layer and the second dielectric layer; depositing a first insulating layer on the second dielectric layer and the capacitor; forming a word line structure on the first insulating layer; depositing a second insulating layer on the word line structure; forming a channel hole in the second insulating layer, the word line structure, and the first insulating layer, wherein the channel hole includes a first section with a trumpet shape opening and a second section below the first section; forming a vertical channel in the second section of the channel hole; and forming a landing pad in the first section of the channel hole.

In some embodiments, forming the channel hole in the second insulating layer includes depositing a lining hard mask layer on the second insulating layer; forming a patterned hard mask layer on the lining hard mask layer; and performing an etching process using the patterned hard mask layer as a mask.

In some embodiments, an etching amount of a first portion of the second insulating layer adjacent the lining hard mask layer is greater than a second portion of the second insulating layer away from the lining hard mask layer.

In some embodiments, a material of the lining hard mask layer includes silicon nitride.

In some embodiments, the method further includes prior to forming the vertical channel, forming a gate dielectric layer on a sidewall of the second section of the channel hole.

In some embodiments, the method further includes prior to forming the landing pad, depositing a conductive film on the vertical channel.

In some embodiments, a material of the conductive film includes indium tin oxide, and a material of the landing pad includes tungsten.

In some embodiments, the method further includes forming a bit line on the second insulating layer and coupled to the landing pad.

In some embodiments, the method further includes prior to depositing the first insulating layer, forming a plug on the capacitor.

In some embodiments, a width of the first section is gradually decreased from top to bottom, and a width of the second section is substantially constant.

Another aspect of the disclosure provides a semiconductor structure including a first dielectric layer disposed on a substrate, a second dielectric layer disposed on the first dielectric layer, a capacitor disposed in the first dielectric layer and the second dielectric layer, a first insulating layer disposed on the second dielectric layer and the capacitor, a word line structure disposed on the first insulating layer, a second insulating layer disposed on the word line structure, a vertical channel penetrating the first insulating layer, the word line, and the second insulating layer and coupled to the capacitor, and a landing pad disposed in the second insulating layer and above the vertical channel. The landing pad has a trumpet shape.

In some embodiments, a width of a top surface of the landing pad is greater than a width of a bottom surface of the landing pad.

In some embodiments, a width of the landing pad is gradually decreased from a top surface to a bottom surface.

In some embodiments, the semiconductor structure further includes a conductive film between the landing pad and the vertical channel.

In some embodiments, a material of the conductive film includes indium tin oxide, and a material of the landing pad includes tungsten.

In some embodiments, the semiconductor structure further includes a gate dielectric layer on a sidewall of the vertical channel.

In some embodiments, the semiconductor structure further includes a bit line disposed on the second insulating layer and coupled to the landing pad.

In some embodiments, the semiconductor structure further includes a plug disposed in the second dielectric layer to connect the capacitor to the vertical channel.

In some embodiments, a material of the vertical channel includes indium gallium zinc oxide.

In some embodiments, a width of the capacitor in the second dielectric layer is greater than a width of the capacitor in the first dielectric layer.

According to the embodiments of the disclosure, the landing pad is formed in the self-alignment holes by deposition and planarization processes, so that the landing pad can be defined without using additional lithography process and additional mask. Therefore, the processes and cost to form the landing pad can be reduced.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure. In the drawings,

FIG. 1 to FIG. 10 are cross-sectional views of different stages of a method of manufacturing a semiconductor structure according to some embodiments of this disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The words “comprise”, “include”, “have”, “contain” and the like used in the present disclosure are open terms, meaning including but not limited to.

In related art, when forming a contact for connecting upper elements and lower element in a semiconductor structure, at least two steps are required. Firstly, a contact is formed in a first dielectric layer after forming capacitors in the first dielectric layer, and then a second dielectric layer is deposited and another contact on the contact is formed in the second dielectric layer. In order to simplify the process for forming the contact and save the use of the photomask, a method of manufacturing the same involving forming a contact on the substrate in one step is provided in embodiments of this disclosure.

It should be noted that when the following figures are illustrated and described as a series of operations or steps, the description order of these operations or steps should not be limited. For example, some operations or steps may be undertaken in a different order than in the present disclosure, or some operations or steps may occur currently, or some operations may not be used, and/or some operations or steps may be repeated.

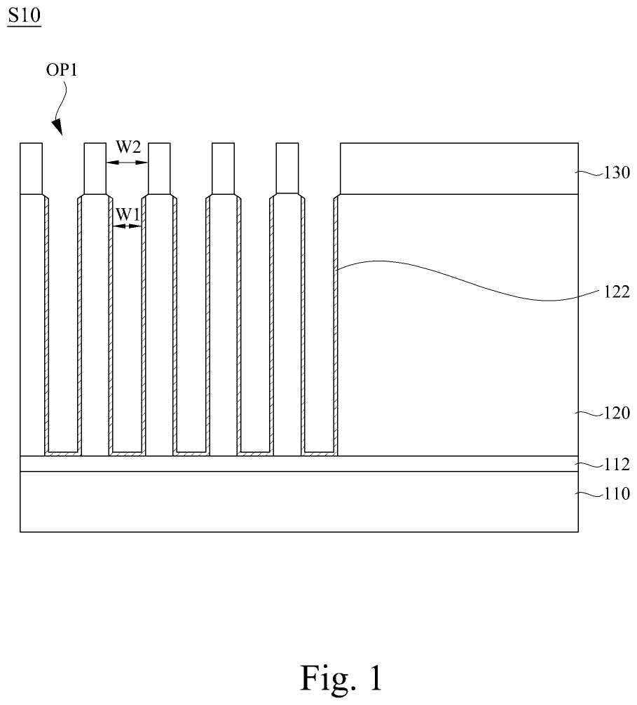

Reference is made to FIG. 1 to FIG. 10. FIG. 1 to FIG. 10 are cross-sectional views of different stages of a method of manufacturing a semiconductor structure according to some embodiments of this disclosure. As shown in FIG. 1, the method of manufacturing the semiconductor structure begins at step S10, a substrate 110 with a conductive layer 112 on the substrate 110 is provided. In some embodiments, the substrate 110 may include silicon, such as crystalline silicon, polycrystalline silicon, or amorphous silicon. The substrate 110 may include an elemental semiconductor, such as germanium. In some embodiments, the substrate 110 may include alloy semiconductors, such as silicon germanium, silicon germanium carbide, gallium indium phosphide, or other suitable materials.

In some embodiments, the substrate 110 may include compound semiconductors, such as silicon carbide (SiC), gallium arsenide (GaAs), indium phosphide (InP), indium arsenide (InAs), or other suitable materials. Moreover, in some embodiments, the substrate 110 can optionally have a semiconductor-on-insulator (SOI) structure. In some embodiments, the conductive layer 112 includes tungsten (W), copper (Cu), or other suitable materials.

A first dielectric layer 120 is deposited on the conductive layer 112. In some embodiments, the first dielectric layer 120 includes tetraethoxysilane (TEOS). In some embodiments, the first dielectric layer 120 is deposited by chemical vapor deposition (CVD), physical vapor deposition (PVD), or other suitable deposition process. Further, a second dielectric layer 130 is deposited on the first dielectric layer 120. The material of the second dielectric layer 130 is different from the material of the first dielectric layer 120. In some embodiments, the second dielectric layer 130 includes nitride, such as SiN. In some embodiments, the second dielectric layer 130 is deposited by CVD, PVD, or other suitable deposition process. In some embodiments, a thickness of the first dielectric layer 120 is greater than a thickness of the second dielectric layer 130.

Next, a plurality of first openings (also called capacitor openings) OP1 is formed in the first dielectric layer 120 and the second dielectric layer 130 until exposing top surfaces of the conductive layer 112. In some embodiments, a width W1 of the first openings OP1 in the second dielectric layer 130 is greater than a width W2 of the first openings OP1 in the first dielectric layer 120.

A plurality of bottom capacitor plates 122 are conformally deposited in the first openings OP1, respectively. Moreover, the bottom capacitor plates 122 are deposited on an inner surface of each of the first openings OP1 in the first dielectric layer 120 without being deposited on an inner surface of each of the first openings OP1 in the second dielectric layer 130 by a selective deposition process. In some embodiments, the material of the bottom capacitor plates 122 includes TiN or other suitable conductive materials.

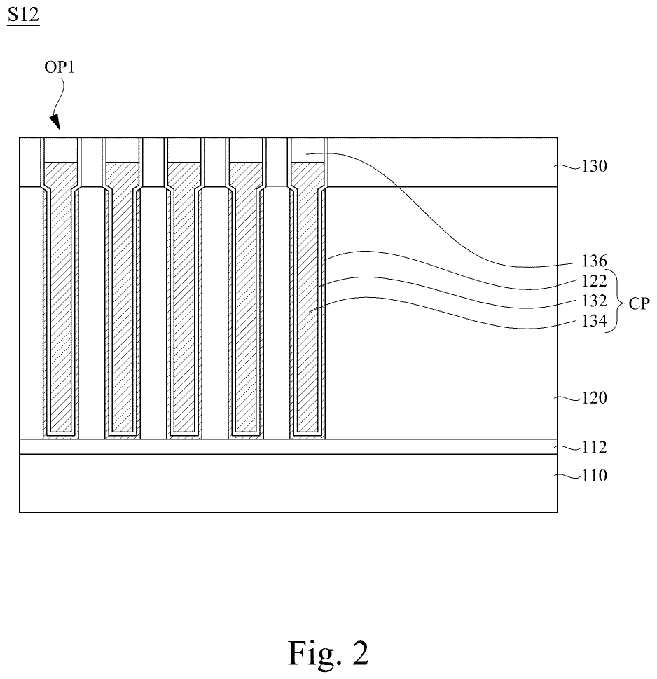

As shown in FIG. 2, the method of manufacturing the semiconductor structure goes to step S12. A plurality of oxide layers 132 are conformally deposited on the bottom capacitor plates 122 and the inner surface of each of the first openings OP1 in the second dielectric layer 130. In some embodiments, the material of the oxide layers 132 includes metal oxide, such as ZrO₂. In some embodiments, the oxide layers 132 are deposited by ALD, or other suitable deposition process.

An electrode material is deposited filling the first openings OP1, and an etch back process is performed to form a plurality of top capacitor plates 134 in the first openings OP1, respectively. In some embodiments, the electrode material of the top capacitor plates 134 includes TiN or other suitable conductive materials.

A plurality of plugs 136 are formed on the top capacitor plates 134, respectively. In some embodiments, the material of the plugs 136 is different from the material of the top capacitor plates 134 for better interface performance. In some embodiments, the material of the plugs 136 includes indium tin oxides (ITO). The top capacitor plates 134, the oxide layers 132, and the bottom capacitor plates 122 are together regarded as capacitors CP.

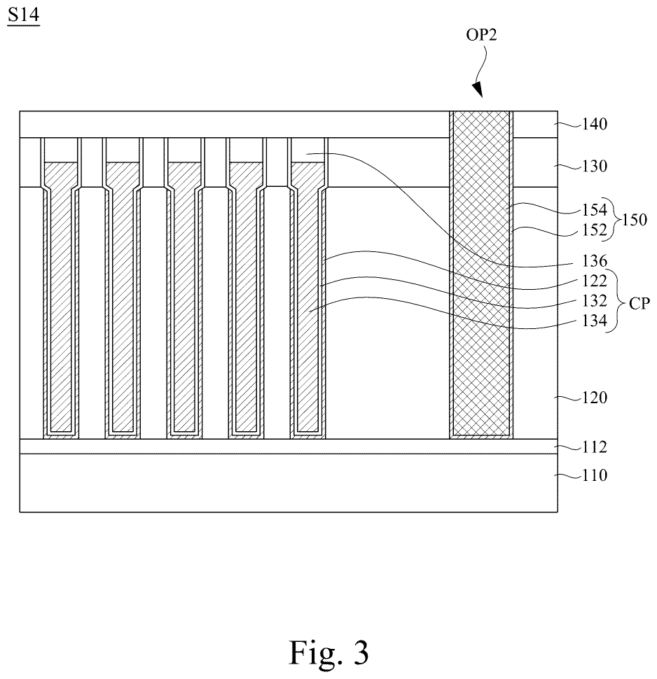

As shown in FIG. 3, the method of manufacturing the semiconductor structure goes to step S14. A first insulating layer 140 is deposited on the second dielectric layer 130 and the plugs 136 after forming the plugs 136. In some embodiments, the material of the first insulating layer 140 includes oxide, such as SiO₂. Subsequently, a second opening (also called a contact opening) OP2 is formed in the first insulating layer 140, the second dielectric layer 130 and the first dielectric layer 120 until exposing a portion of the top surface of the conductive layer 112. In some embodiments, the second opening OP2 is formed by a reactive ion etching (RIE) process. A first conductive layer 152 is conformally deposited in the second opening OP2. In some embodiments, the material of the first conductive layer 152 includes TiN or other suitable conductive materials.

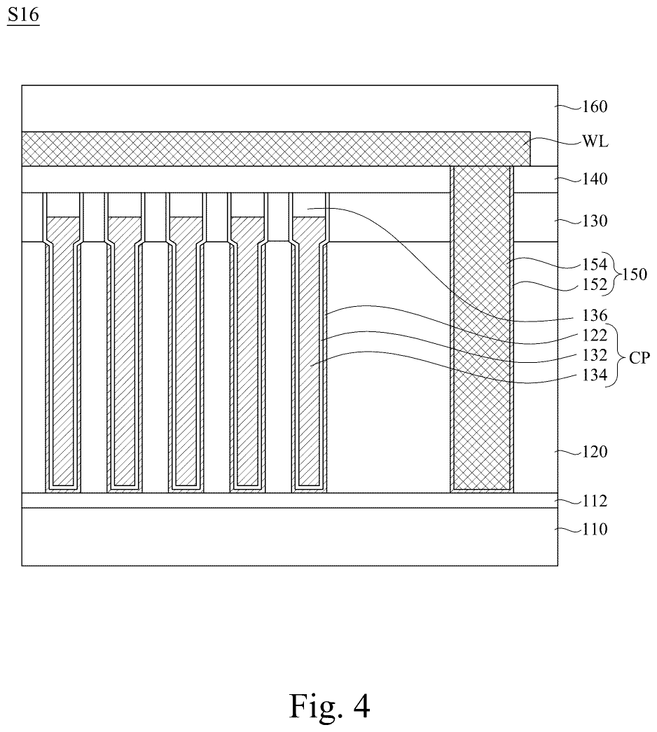

Then, a second conductive layer 154 is deposited on the first conductive layer 152 and filled in the second opening OP2, and the excessive second conductive layer 154 is removed by a planarization process. Therefore, a word line contact 150 including the first conductive layer 152 and the second conductive layer 154 on the first conductive layer 152 is formed. In some embodiments, the material of the second conductive layer 154 includes W, Cu, or other suitable materials. In some embodiments, the second conductive layer 154 is filled by CVD, PVD, or other suitable deposition process. In some embodiments, the planarization process includes chemical mechanical polishing (CMP). Additionally, a top surface of the word line contact 150 and a top surface of the first insulating layer 140 are coplanar. The word line contact 150 is utilized to connect the conductive layer 112 and a word line structure WL (as shown in FIG. 4 later). In this way, the process for forming the word line contact 150 may be simplified and the use of the photomask may be saved.

As shown in FIG. 4, the method of manufacturing the semiconductor structure goes to step S16. A word line structure WL is deposited on the first insulating layer 140 and the word line contact 150, and a second insulating layer 160 is deposited on the word line structure WL. A portion of a bottom surface of the word line structure WL directly contacts the top surface of the word line contact 150 such that the resistance-capacitance (RC) value of the word line structure WL and the capacitors CP may be reduced. In some embodiments, the material of the word line structure WL includes W, Cu, or other suitable materials. In some embodiments, the word line structure WL is formed by CVD, PVD, or other suitable deposition process. In some embodiments, the word line structure WL has a protruding portion protruding perpendicular to an axis of the word line contact 150 and away from the capacitors CP. Moreover, a top surface of each of the plugs 136 is lower than the top surface of the word line structure WL.

In some embodiments, the material of the second insulating layer 160 includes nitride, oxide, or other suitable materials, such as SiO₂. The thickness of the second insulating layer 160 is thicker than the thickness of the first insulating layer 140 and the word line structure WL. In some embodiments, a portion of the second insulating layer 160 is disposed aside the word line structure WL and is in contact with the first insulating layer 140.

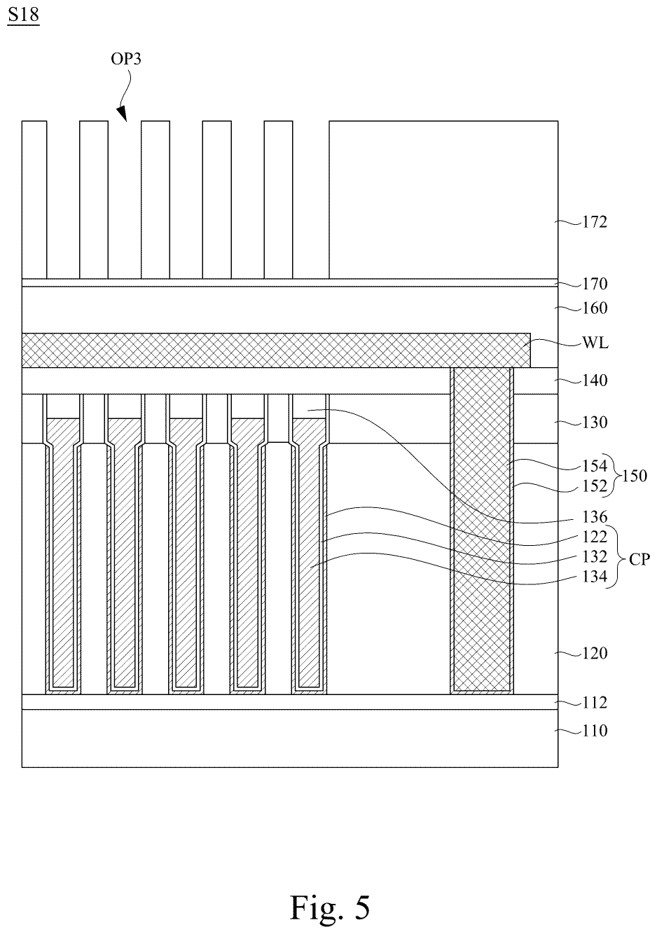

As shown in FIG. 5, the method of manufacturing the semiconductor structure goes to step S18. A lining hard mask layer 170 is deposited on the second insulating layer 160. The material of the lining hard mask layer 170 is different from the material of the second insulating layer 160. In some embodiments, the material of the lining hard mask layer 170 includes nitride, such as SiN. In some embodiments, the lining hard mask layer 170 is deposited by an atomic layer deposition (ALD) process such that the lining hard mask layer 170 is conformally deposited on the second insulating layer 160 with a thin thickness.

After the lining hard mask layer 170 is deposited on the second insulating layer 160, a patterned hard mask layer 172 is formed on the lining hard mask layer 170. The patterned hard mask layer 172 is formed by CVD, PVD, or other suitable deposition process, and the thickness of the patterned hard mask layer 172 is greater than the thickness of the lining hard mask layer 170. Additionally, the material of the patterned hard mask layer 172 is different from the material of the lining hard mask layer 170. The patterned hard mask layer 172 includes a plurality of third openings OP3 corresponding to the capacitors CP. The third openings OP3 of the patterned hard mask layer 172 are at least partially overlapping the capacitors CP. The lining hard mask layer 170 is remained covering the entire top surface of the second insulating layer 160 after the third openings OP3 of the patterned hard mask layer 172 are formed.

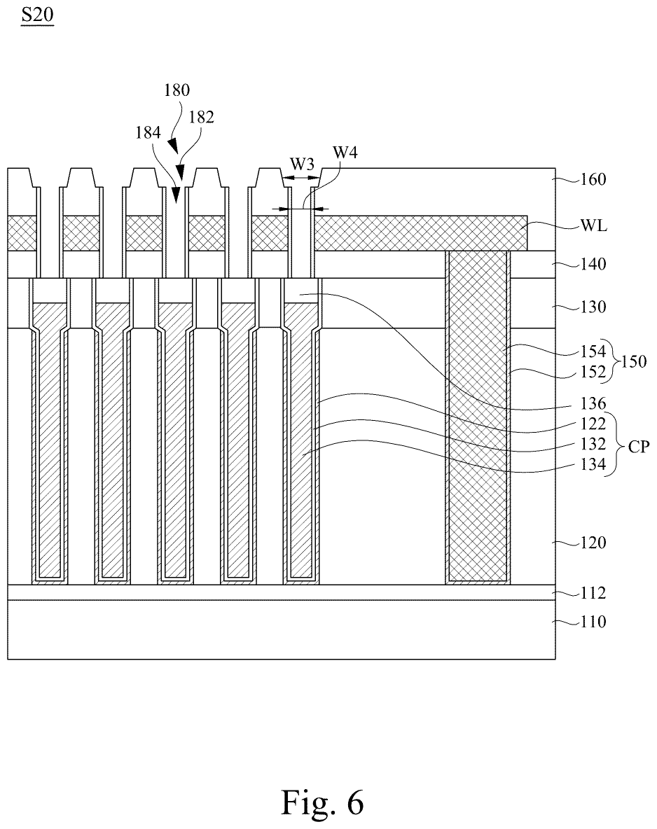

As shown in FIG. 6, the method of manufacturing the semiconductor structure goes to step S20. An etching process is performed using the patterned hard mask layer 172 (as shown in FIG. 5) as a mask, and portions of the first insulating layer 140, the word line structure WL, and the second insulating layer 160 uncovered by the patterned hard mask layer 172 are removed after the etching process, thereby forming a plurality of channel holes 180 in the first insulating layer 140, the word line structure WL, and the second insulating layer 160. The top surfaces of the plugs 136 are at least partially exposed by the channel holes 180.

In some embodiments, the lining hard mask layer 170 (as shown in FIG. 5) and the patterned hard mask layer 172 may be completely consumed during etching process. In some other embodiments, the lining hard mask layer 170 and the patterned hard mask layer 172 may not be completely consumed and are removed by an additional cleaning process. In some embodiments, the etching process is a reactive-ion etching process.

Because of the lining hard mask layer 170 between the patterned hard mask layer 172 and the second insulating layer 160, and the etching process etches through the lining hard mask layer 170, the etching amount of the second insulating layer 160 adjacent the lining hard mask layer 170 is different from the rest of the second insulating layer 160. More particularly, the etching amount of a first portion of the second insulating layer 160 adjacent the lining hard mask layer 170 is greater than a second portion of the second insulating layer 160 away from the lining hard mask layer 170. As a result, each of the channel holes 180 has a first section 182 with a trumpet shape opening and a second section 184 below the first section 182 at the second insulating layer 160. In some embodiments, the width W3 of the first section 182 is greater than the width W4 of the second section 184. In some embodiments, the width W3 of the first section 182 is gradually decreased from top to bottom, and the width W4 of the second section 184 is substantially constant.

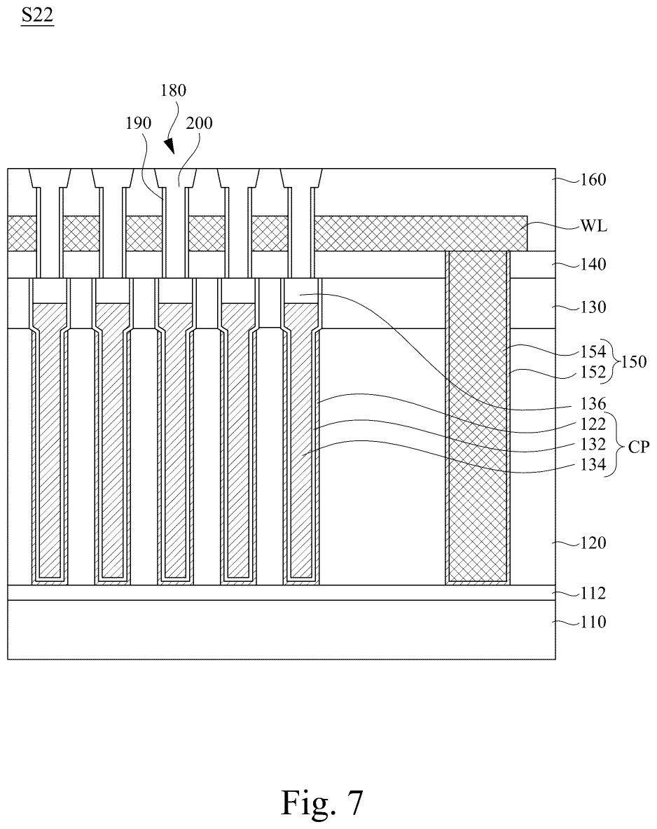

As shown in FIG. 7, the method of manufacturing the semiconductor structure goes to step S22. A gate dielectric layer 190 is formed on the sidewall of each of the channel holes 180. In some embodiments, the gate dielectric layer 190 is formed by comformally depositing a dielectric layer on sidewalls and bottom surfaces of the channel holes 180, and then a directional etching process is performed to remove the lateral portions of the dielectric layer such that the remained vertical portions of the dielectric layer are the gate dielectric layers 190 on the sidewall of the channel holes 180. More particularly, in some embodiments, the gate dielectric layers 190 are disposed on the sidewalls of the second section 184 (as shown in FIG. 6) of the channel holes 180 and are not disposed on the sidewalls of the first section 182 (as shown in FIG. 6) with the trumpet shape opening of the channel holes 180. The top surfaces of the plugs 136 are exposed after the gate dielectric layers 190 are formed.

Then, a conductive material is deposited filling the channel holes 180, and a planarization process is performed to remove the exceeded portions of the conductive material. Therefore, a plurality of vertical channels 200 are formed in the channel holes 180, respectively. In some embodiments, the material of the vertical channels 200 is uniform conductive material. For example, the material of the vertical channels 200 can be indium gallium zinc oxide (IGZO).

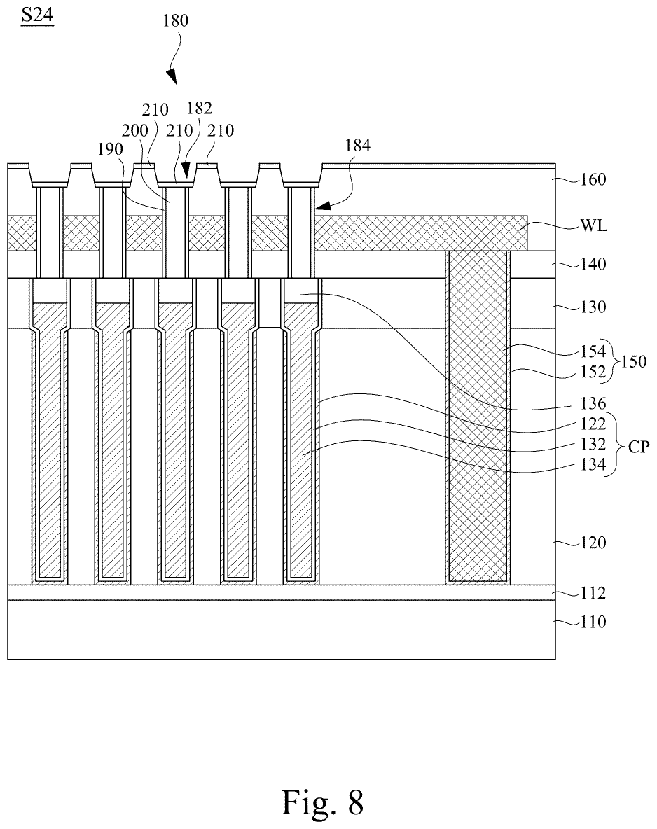

As shown in FIG. 8, the method of manufacturing the semiconductor structure goes to step S24. An etching back process is performed to recess the vertical channels 200. In some embodiments, the portions of the vertical channels 200 at the first section 182 of the channel holes 180 are removed, and the first sections 182 of the channel holes 180 with the trumpet shape are revealed again. The remained portions of the vertical channels 200 are substantially level with the gate dielectric layers 190.

The first sections 182 of the channel holes 180 with the trumpet shape are formed directly above the vertical channels 200, so that the first sections 182 of the channel holes 180 can be also regarded as self-alignment holes on the vertical channels 200.

After the first sections 182 of the channel holes 180 with the trumpet shape are revealed, a conductive film 210 is deposited by a directional depositing process. The conductive film 210 is deposited on the top surfaces of the vertical channels 200 and the top surfaces of the second insulating layer 160. The conductive film 210 is not deposited on the sidewalls of the first sections 182 of the channel holes 180. The material of the conductive film 210 is different from the material of the vertical channels 200. In some embodiments, the material of the conductive film 210 is indium tin oxide (ITO).

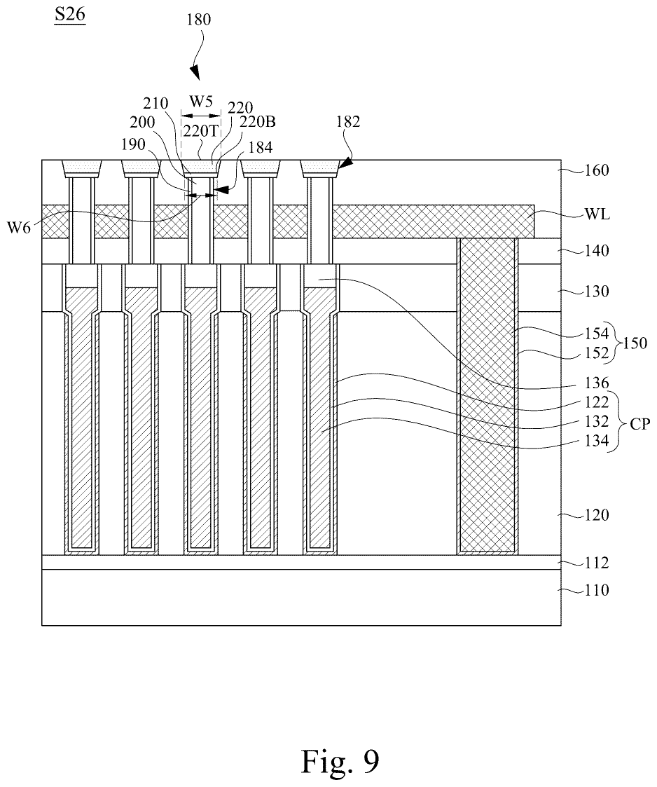

As shown in FIG. 9, the method of manufacturing the semiconductor structure goes to step S26. A metal layer is deposited on the structure as shown in FIG. 8, and a planarization process is performed to remove exceeded portions of the metal layer, portions of the second insulating layer 160, and portions of the conductive film 210 on the second insulating layer 160. The remained portions of the metal layer are disposed in the first sections 182 of the channel holes 180 as landing pads 220. Each of the landing pads 220 has a trumpet shape. The width W5 of the top surface 220T of the landing pad 220 is greater than the width W6 of the bottom surface 220B of the landing pad 220, and the width of the landing pad 220 is gradually decreased from the top surface 220T to the bottom surface 220B.

In some embodiments, the material of the landing pads 220 is different from the material of the conductive film 210. In some embodiments, the material of the landing pads 220 is tungsten. The conductive film 210 between the landing pads 220 and the vertical channels 200 can improve the interface performance between the landing pads 220 and the vertical channels 200.

The landing pads 220 are formed in the first sections 182 of the channel holes 180 which are self-alignment holes by deposition and planarization processes, so that the landing pads 220 can be defined without using additional lithography process and additional mask. Therefore, the landing pads 220 can be formed by series of self-alignment fabrication processes.

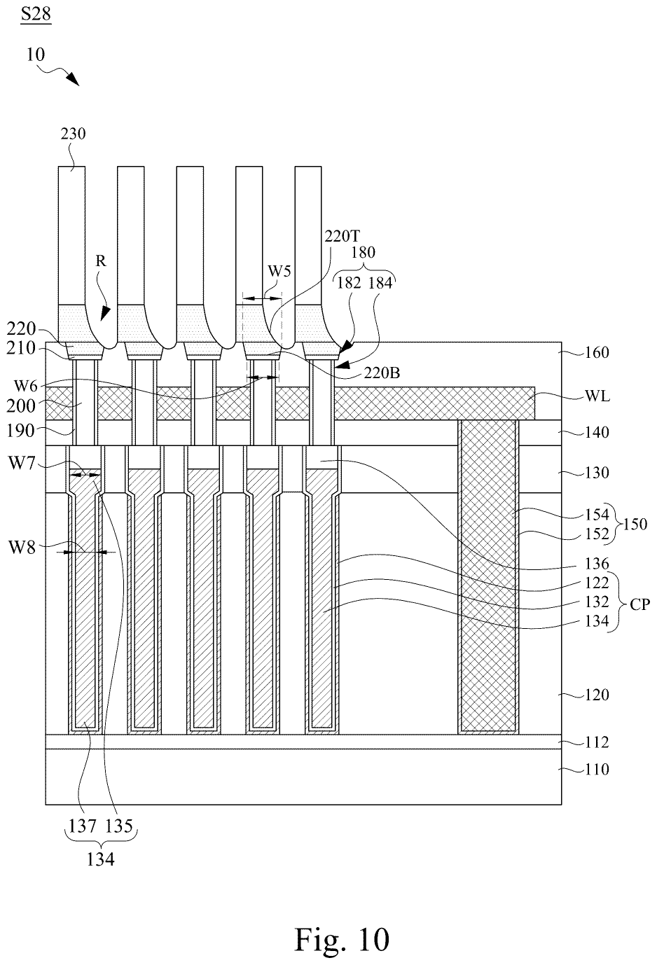

As shown in FIG. 10, the method of manufacturing the semiconductor structure goes to step S28. After the landing pads 220 are formed on the vertical channels 200, a plurality of bit lines 230 are formed on and coupled to the landing pads 220, respectively. In some embodiments, a plurality of recesses R are formed between the bit lines 230, and the landing pads 220 are also recessed such that the top surfaces 220T of the landing pads 220 are concave surfaces.

In some embodiments, the plugs 136 on the capacitors CP serve as drain electrodes, and the landing pads 220 connected to the bit lines 230 serve as source electrodes. The plugs 136, the vertical channels 200, the landing pads 220, and the word line structure WL together serve as vertical transistors. The vertical transistors and the corresponding capacitors CP together form a memory array.

In some embodiments of the disclosure, the semiconductor structure 10 having trumpet shape landing pads 220 is provided. The semiconductor structure 10 includes the substrate 110 with the conductive layer 112, the first dielectric layer 120 on the substrate 110, the second dielectric layer 130 on the first dielectric layer 120, and the plurality of capacitors CP disposed in the first dielectric layer 120 and the second dielectric layer 130. Each of the capacitors CP includes the top capacitor plate 134, the oxide layer 132, and the bottom capacitor plate 122, in which the bottom capacitor plate 122 is U shape and contacts the conductive layer 112.

In some embodiments, the bottom capacitor plate 122 is disposed on the sidewall of the first dielectric layer 120, and the oxide layer 132 directly contacts the sidewall of the second dielectric layer 130. The top capacitor plate 134 has a first portion 135 within the second dielectric layer 130 and a second portion 137 within the first dielectric layer 120. The width W7 of the first portion 135 of the top capacitor plate 134 is greater than the width W8 of the second portion 137 of the top capacitor plate 134.

The semiconductor structure 10 further includes the plurality of plugs 136 disposed on the top capacitor plates 134, respectively. The top surface of the plugs 136 is coplanar with the top surface of the oxide layers 132 and the top surface of the second dielectric layer 130. The top surface of the top capacitor plates 134 is below the top surface of the plugs 136.

The semiconductor structure 10 further includes the first insulating layer 140 disposed on the second dielectric layer 130, the word line structure WL, and the second insulating layer 160 is deposited on the word line structure WL. The semiconductor structure 10 further includes the word line contact 150 connecting the word line structure WL to the conductive layer 112. In some embodiments, the material of the word line structure WL and the word line contact 150 includes W, Cu, or other suitable materials.

The semiconductor structure 10 further includes the plurality of vertical channels 200 penetrating the first insulating layer 140, the word line structure WL, the second insulating layer 160, and the gate dielectric layers 190 disposed between the vertical channels 200 and the word line structure WL. The vertical channels 200 directly contact the plugs 136 above the capacitors CP. In some embodiments, the top surface of the vertical channels 200 is below the top surface of the second insulating layer 160.

The semiconductor structure 10 further includes the plurality of landing pad 220 disposed on the vertical channels 200, respectively. Each of the landing pads 220 has a trumpet shape. The width W5 of the top surface 220T of the landing pad 220 is greater than the width W6 of the bottom surface 220B of the landing pad 220, and the width of the landing pad 220 is gradually decreased from the top surface 220T to the bottom surface 220B. The semiconductor structure 10 further includes the conductive film 210 between the landing pads 220 and the vertical channels 200 to improve the interface performance between the landing pads 220 and the vertical channels 200.

According to the embodiments of the disclosure, the landing pads are formed in the self-alignment holes by deposition and planarization processes, so that the landing pads can be defined without using additional lithography process and additional mask. Therefore, the processes and cost to form the landing pads can be reduced.

It will be apparent to those skilled in the art that various modifications and variations can be made to the structure of the present disclosure without departing from the scope or spirit of the disclosure. In view of the foregoing, it is intended that the present disclosure con modifications and variations of this disclosure provided they fall within the scope of the following claims and their equivalents.

What is claimed is:

1. A method of fabricating semiconductor structure, comprising:
depositing a first dielectric layer on a substrate;
depositing a second dielectric layer on the first dielectric layer;
forming a capacitor in the first dielectric layer and the second dielectric layer;
depositing a first insulating layer on the second dielectric layer and the capacitor;
forming a word line structure on the first insulating layer;
depositing a second insulating layer on the word line structure;
forming a channel hole in the second insulating layer, the word line structure, and the first insulating layer, wherein the channel hole comprises a first section with a trumpet shape opening and a second section below the first section;
forming a vertical channel in the second section of the channel hole; and
forming a landing pad in the first section of the channel hole.

2. The method of claim 1, wherein forming the channel hole in the second insulating layer comprises:
depositing a lining hard mask layer on the second insulating layer;
forming a patterned hard mask layer on the lining hard mask layer; and
performing an etching process using the patterned hard mask layer as a mask.

3. The method of claim 2, wherein an etching amount of a first portion of the second insulating layer adjacent the lining hard mask layer is greater than a second portion of the second insulating layer away from the lining hard mask layer.

4. The method of claim 2, wherein a material of the lining hard mask layer comprises silicon nitride.

5. The method of claim 1, further comprising:
prior to forming the vertical channel, forming a gate dielectric layer on a sidewall of the second section of the channel hole.

6. The method of claim 1, further comprising:
prior to forming the landing pad, depositing a conductive film on the vertical channel.

7. The method of claim 6, wherein a material of the conductive film comprises indium tin oxide, and a material of the landing pad comprises tungsten.

8. The method of claim 1, further comprising forming a bit line on the second insulating layer and coupled to the landing pad.

9. The method of claim 1, further comprising:
prior to depositing the first insulating layer, forming a plug on the capacitor.

10. The method of claim 1, wherein a width of the first section is gradually decreased from top to bottom, and a width of the second section is substantially constant.

11. A semiconductor structure, comprising:
a first dielectric layer disposed on a substrate;
a second dielectric layer disposed on the first dielectric layer;
a capacitor disposed in the first dielectric layer and the second dielectric layer;
a first insulating layer disposed on the second dielectric layer and the capacitor;
a word line structure disposed on the first insulating layer;
a second insulating layer disposed on the word line structure;
a vertical channel penetrating the first insulating layer, the word line, and the second insulating layer and coupled to the capacitor; and
a landing pad disposed in the second insulating layer and above the vertical channel, wherein the landing pad has a trumpet shape.

12. The semiconductor structure of claim 11, wherein a width of a top surface of the landing pad is greater than a width of a bottom surface of the landing pad.

13. The semiconductor structure of claim 11, wherein a width of the landing pad is gradually decreased from a top surface to a bottom surface.

14. The semiconductor structure of claim 11, further comprising a conductive film between the landing pad and the vertical channel.

15. The semiconductor structure of claim 14, wherein a material of the conductive film comprises indium tin oxide, and a material of the landing pad comprises tungsten.

16. The semiconductor structure of claim 11, further comprising a gate dielectric layer on a sidewall of the vertical channel.

17. The semiconductor structure of claim 11, further comprising a bit line disposed on the second insulating layer and coupled to the landing pad.

18. The semiconductor structure of claim 11, further comprising a plug disposed in the second dielectric layer to connect the capacitor to the vertical channel.

19. The semiconductor structure of claim 11, wherein a material of the vertical channel comprises indium gallium zinc oxide.

20. The semiconductor structure of claim 11, wherein a width of the capacitor in the second dielectric layer is greater than a width of the capacitor in the first dielectric layer.
